(19) United States
(12) Patent Application Publication
(10) Pub. No.: US 2009/0192927 A1
(43) Pub. Date: Jul. 30, 2009

(54) Enhanced power outlet system incorporating a smart receptacle

(76) Inventors: Michel J. Berg, Rochester, NY (US); Javier M. Barrantes, Rochester, NY (US); Erin M. Bruemmer, Rochester, NY (US); Igar J. Lapiczak, Rochester, NY (US); Sashank Nanduri, Rochester, NY (US)

Correspondence Address: Dennis M. Connolly, 999 Lehigh Station Road, Henrietta, NY, 14467, US

(21) Appl. No.: 11/899,435

(22) Filed: Sep. 6, 2007

Related U.S. Application Data
(60) Provisional application No. 60/844,258, filed on Sep. 13, 2006.

(51) Int. Cl. G06Q 30/00; H01R 29/00; H01R 13/44; G01R 21/00; G06Q 50/00

(52) U.S. Cl. 705/34; 439/188; 439/133; 702/62; 705/412

(57) ABSTRACT

The present invention relates to the field of enhanced electrical receptacles (outlets) and plugs. It is comprised of a system to identify and validate the user with acknowledgement of authorization. Power is supplied to authorized users and their power usage can be monitored, stored, and communicated to a remote device. Said usage can be used to charge the user a fee or to assess work efficiency.

This application claims the benefit of U.S. Provisional Patent Application Ser. No. 60/844,258, filed Sep. 13, 2006, which is hereby incorporated by reference in its entirety.

### FIELD OF THE INVENTION

The present invention relates to the field of enhanced electrical receptacles (outlets) and plugs. Specifically it relates to receptacles that identify the user, control power supply, and monitor power usage. In this situation user refers to a device, human, or group of either forming an account. Power at the receptacle can be enabled to an authorized user whose power consumption can be tracked. The data associated with a user can be stored and processed locally or remotely. A specific user can be charged based on power usage data accumulated over time. It achieves these features with a receptacle that has systems to identify the user, authorize the user, control power usage, and monitor power consumption and with a method to account for power usage, pay for the power directly or through an intermediary, and charge the account a fee based on usage.

### BACKGROUND OF THE INVENTION

### Discussion of Prior Art

U.S. Pat. No. 6,183,264 B13 issued to Harsányi on Feb. 6, 2001 discloses a safety outlet receptacle with a corresponding plug that renders the outlet inactive and unable to send electrical current unless activated using the corresponding plug. This invention uses a magnetic switch and spring to change the activity state of the outlet receptacle. U.S. Pat. No. 6,717,077 issued to Chevarie, et al. on Apr. 6, 2004 discloses a spring based receptacle system that is inactive unless a plug is inserted. Likewise, U.S. Pat. No. 4,591,732 issued to Neuenschwander on May 27, 1986 discloses a relay system to inactivate the receptacle when the plug is not inserted. U.S. Pat. No. 6,229,107 issued to Flint and Shelton on May 8, 2001 discloses a safety electrical receptacle that causes it to be inactive until the proper mating connector plug is fully inserted into the socket. All of these inventions are designed to prevent accidental shock when non plug connectors are inserted or when plugs are not fully inserted into the receptacle primarily as a child safety device. None use a system to validate the specific plug being inserted or identify the user to control the power to the receptacle.

Similarly, U.S. Pat. No. 6,552,888 issued to Weinberger on Apr. 22, 2003 discloses an electrical safety outlet for accepting a plug to provide power to electrical appliances including a power supply and an intelligent circuitry for controlling the power supply to the electrical outlet (receptacle). This device is able to determine temperature conditions in the outlet, that a mechanical plug is inserted fully into the outlet, load presence, and current capacity to the outlet. This invention is designed to prevent accidental shock as well as overload of the outlet circuitry. U.S. Pat. No. 4,915,639 issued to Cohn and Kelly on Apr. 10, 1990 discloses an intelligent AC outlet which uses coded information on the plug of a device indicating the load of the device which is read by a sensor and microprocessor circuit within the receptacle after the plug is inserted. This invention is designed to prevent excessive current draw by providing the microprocessor information about the current draw of the device; the load information is then used by the microprocessor to turn on the power if the current draw is within acceptable limits. Excepting current draw, this invention does not encompass validation or identifying information regarding acceptability of the user or device. These two inventions relate to safety of the wiring and circuitry within the receptacle and feed lines. The current invention claimed in this document is not specifically concerned with current draw or circuit overload, but validation and identification of the user for a multiplicity of reasons as described herein.

The following patents disclose safety power outlet inventions: U.S. Pat. No. 6,894,221, U.S. Pat. No. 6,537,089, U.S. Pat. No. 6,455,789, U.S. Pat. No. 5,113,045, U.S. Pat. No. 4,846,707 and U.S. Pat No. 3,990,758. These inventions use a variety of schemes to block the slots in the receptacles or ensure that plugs are appropriately inserted into the receptacle for child safety and do not overlap the present invention.

U.S. Pat. No. 5,910,776 issued to Black on Jun. 8, 1999 utilizes radio frequency to identify, locate and track equipment however it does not use the radio frequency technology to validate specific devices or control power to devices.

U.S. Pat. No. 6,907,278 B2 issued to Herle on Jun. 14, 2005 discloses a power monitoring device for use in an electronic device that operates in a low power mode from a removable battery module. This device monitors the power from the module. It uses a sampling circuitry for measuring power from a battery using a microcontroller to store data or do calculations. This invention is directed to apparatuses and methods for testing the power consumption of a wireless mobile station and, in particular, to a battery replacement module for testing the power consumption of a mobile phone. This invention does not measure AC power at a receptacle and it does not keep track of individual power dissipation according to a specific user.

U.S. Pat. No. 6,445,188 issued to Lutz, et al. on Sep. 3, 2002 discloses an intelligent, self monitoring AC power plug that consists of an electronic circuit assembled onto a miniature printed circuit board with current and voltage sensors used to determine the power being consumed by the loading device in order for data to be exchanged with a PC or computer or other programmer/reader device. This patent is exclusively concerned with power usage of a device assessed through its plug and does not identify, validate, or authorize a specific user or control power. It also does not concern itself with the receptacle.

Thus, there is a need in the art for an enhanced power outlet system that is able to identify and validate the user, control access to power, and monitor, store and communicate data about usage of power for purposes of authorization and accounting.

### References Cited:

### U.S. Patent Documents

### D464,865 S 10/2002 Luu . . . D8/353

U.S. Pat. No. 5,816,682 10/1998 Marischen . . . 362/84
U.S. Pat. No. 6,906,617 6/2005 Meulen et al . . . 340/310.01
U.S. Pat. No. 6,183,264 B1 2/2001 Harsányi . . . 439/38
U.S. Pat. No. 6,907,278 B2 6/2005 Herle . . . 455/572
U.S. Pat. No. 4,915,639 4/1990 Cohn et al . . . 439/188
U.S. Pat. No. 6,552,888 4/2003 Weinberger . . . 361/57
U.S. Pat. No. 6,894,221 5/2005 Gorman . . . 174/53
U.S. Pat. No. 6,537,089 3/2003 Montague . . . 439/145
U.S. Pat. No. 6,455,789 9/2002 Allison . . . 200/51.09
U.S. Pat. No. 5,113,045 5/1991 Crofton . . . 200/51.09
U.S. Pat. No. 4,846,707 7/1989 Pirkle . . . 439/142
U.S. Pat. No. 3,990,758 11/1976 Petterson . . . 439/138
U.S. Pat. No. 5,662,408 9/1997 Marischen . . . 362/641
U.S. Pat. No. 5,910,776 6/1999 Black . . . 340/10.1
U.S. Pat. No. 6,229,107 5/2001 Flint et al . . . 200/51.09
U.S. Pat. No. 6,717,077 4/2004 Chevarie et al . . . 200/51.09
U.S. Pat. No. 4,591,732 5/1986 Neuenschwander . . . 307/140
U.S. Pat. No. 6,445,188 9/2002 Lutz, et al . . . 324/508

### SUMMARY OF THE INVENTION

### Objectives and Advantages

Standard receptacles have the simple task of providing power to a standard plug. An enhanced power outlet system will additionally have knowledge about the device or user, control power, and monitor, store, and communicate usage data. This functionality can be accomplished by using a combination of the following features: internal circuitry to identify a specific device or user that is employed with an identifier associated with an external device or user, a sensor to detect that an associated device plug is fully inserted, circuitry to enable and disable power to the receptacle, circuitry to monitor and store power consumption data of the identified devices, a method to transmit said data to an external data device, and audio, visual, or tactile confirmation that the power supply is enabled. The receptacle has the capacity to only be powered if the user is validated.

Accordingly, several objects and advantages of this invention are:

It is therefore an object of the present invention to provide a smart receptacle with a system to identify the user and circuitry to control power.

A further object of the present invention is to provide a receptacle with a system to identify the user and circuitry to monitor usage.

It is yet another object of the present invention to provide a system that controls power to an authorized user at the receptacle.

Another object of the present invention is to provide a system to validate the specific plug being inserted prior to providing power to the receptacle.

An additional object of the present invention is to provide a system to identify a specific user prior to providing power to the receptacle.

Another object of the present invention is to provide a system to validate a specific user prior to providing power to the receptacle.

An additional object of the present invention is to provide a system to authorize a specific user prior to providing power to the receptacle.

Another object of the present invention is to provide a system that requires full plug insertion prior to providing power to the receptacle.

A further object of the present invention is to measure AC power at a receptacle and record individual power usage by a specific user.

An additional object of the present invention is to monitor AC power usage at a receptacle by a specific user.

Another object of the present invention is to use the radio frequency technology to validate a specific device or user prior to providing power to the receptacle.

Another object of the present invention is to reduce the risk of accidental electrocution by not providing power to the receptacle until a valid device is detected and the corresponding plug is fully inserted into the receptacle.

A further object of the present invention is to provide editing privileges of the system controlling and monitoring power at the receptacle to an operator via an interface.

An additional object of the present invention is to provide a system that charges a specific user for their power usage.

Another object of the present invention is to provide a system that monitors power usage to assess work efficiency.

A further object of the present invention is for the enhanced power outlet system to use a magnetic card reader, an optical reader, a bar code reader, an RFID reader, a biometric reader, or other technologies to identify a specific user or device.

Another object of the present invention is to provide a smart receptacle with an external enclosure to be used with an existing outlet.

Another object of the present invention is to provide a smart receptacle designed to be built into a structure.

Further objects and advantages will become apparent from a consideration of the ensuing description and drawings.

### SUMMARY

In accordance the present invention is an enhanced power outlet system incorporating a smart receptacle. It is comprised of a system to identify, validate, and authorize the user with acknowledgement of authorization to the user. Power is supplied to authorized users and their power usage is monitored, stored, and communicated to a remote processor. Said power usage is then used to measure work efficiency or charge the user a fee.

### BRIEF DESCRIPTION OF THE DRAWINGS

FIG. 1 is a table of the descriptions of the designators for FIG. 2 through FIG. 6.

FIG. 2 is the front view of the Enhanced Power Outlet System and Smart Receptacle and plug assembly including identifier in a card.

FIG. 3 is the isometric view of the Enhanced Power Outlet System with Smart Receptacle and plug assembly including identifier associated with the plug.

FIG. 4 is the back isometric view of the external Smart Receptacle.

FIG. 5 is an isometric view of the adaptor.

FIG. 6 is a block diagram of the Enhanced Power Outlet System with Smart Receptacle.

### DETAILED DESCRIPTION OF THE INVENTION

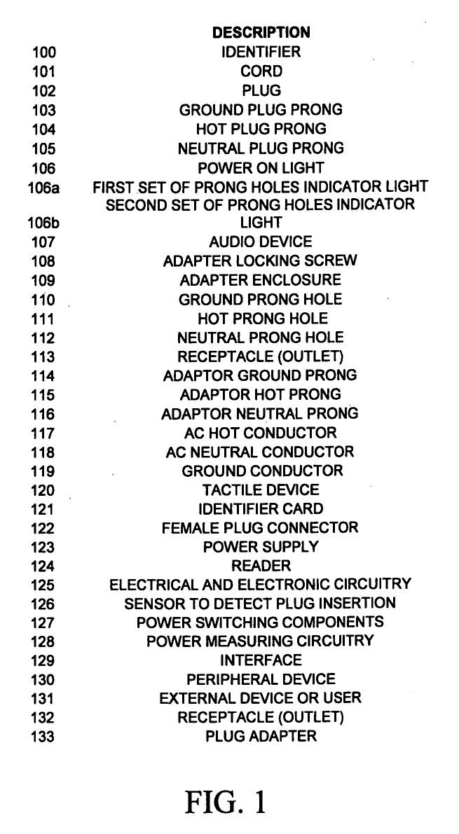

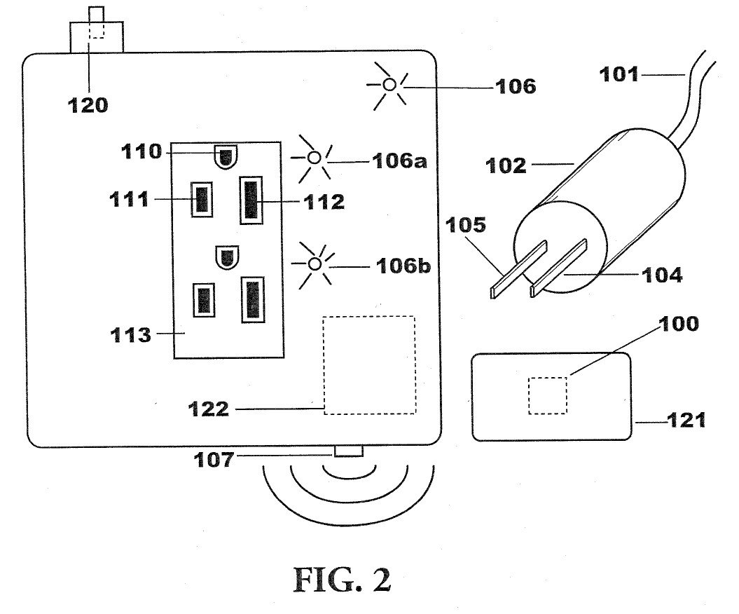

Referring now to the drawings, FIG. 1 is a table of the descriptions of the designators for FIG. 2 through FIG. 6.

FIG. 2 is a front view of the Enhanced Power Outlet System. The reader 122 and associated circuitry (internal, not depicted) has an authorization list of valid identifier codes. When the identifier card 121 with the identifier 100 is read by reader 122 the identifier code is compared to the codes in the authorization list and validity is determined. Upon verification of a valid identifier, electronic circuitry turns on the audio 107, activates the tactile 120 device, and the power on light 106 to acknowledge to the user that authorization has occurred. Power is enabled to one set of prong holes indicated by indicator light 106a or 106b. The plug prongs 104, 105 of the plug 102 are inserted into the prong holes 110-112 of the outlet 113. The identifier 100 can be attached to the plug 102 or cord 101 or be in a user held apparatus such as a credit card 121.

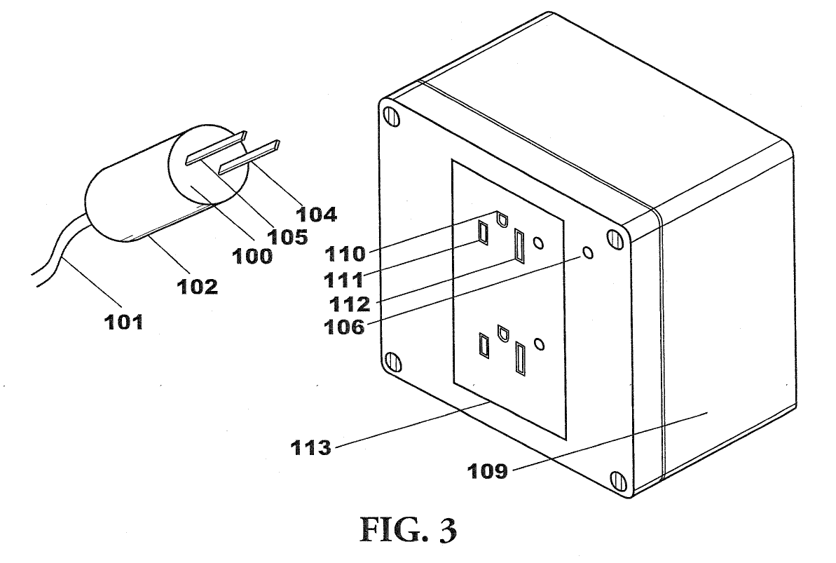

FIG. 3 is an isometric view of the Enhanced Power Outlet System with external Smart Receptacle with receptacle and plug assembly including identifier 100 attached to plug 102 and reader (not pictured) internal to the enclosure 109. The external Smart Receptacle is plugged into an existing outlet. It can be secured to the outlet with an internal locking screw or other mechanism, not pictured.

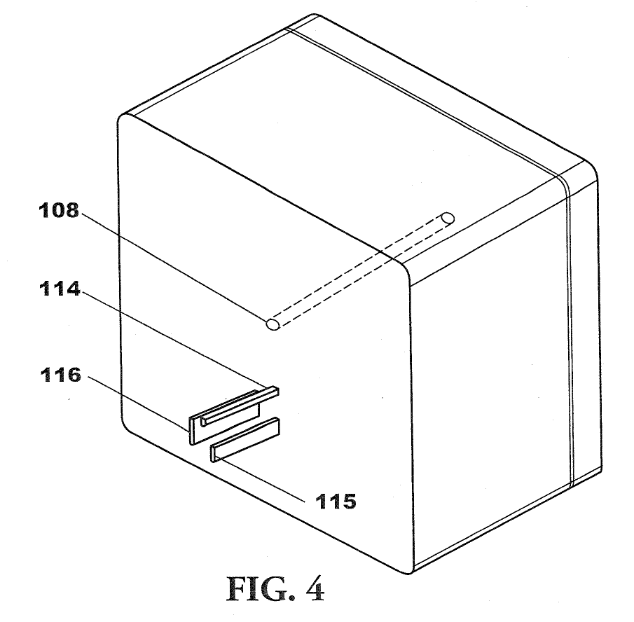

FIG. 4 is the back isometric view of the external Smart Receptacle. The prongs 114-116 of the external Smart Receptacle enclosure can be inserted into an existing wall receptacle for power supply. It can be secured to the outlet with an internal locking screw 108.

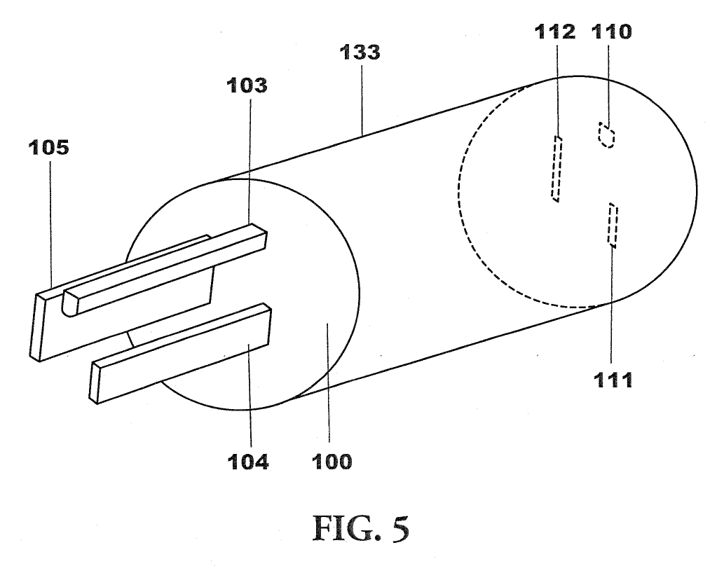

FIG. 5 is an isometric view of a pass-through adaptor with the identifier 100. The identifier 100 is embedded in the plug 102. The AC ground, hot, and neutral prongs are 103, 104 and 105 respectively. The associated prong-holes 110-112 are located on a different side than the prongs 103-105 of the pass-through adaptor. The pass-through adaptor can include an extension cord with the prong holes at one end and prongs on the other end; the identifier is located near the prong end.

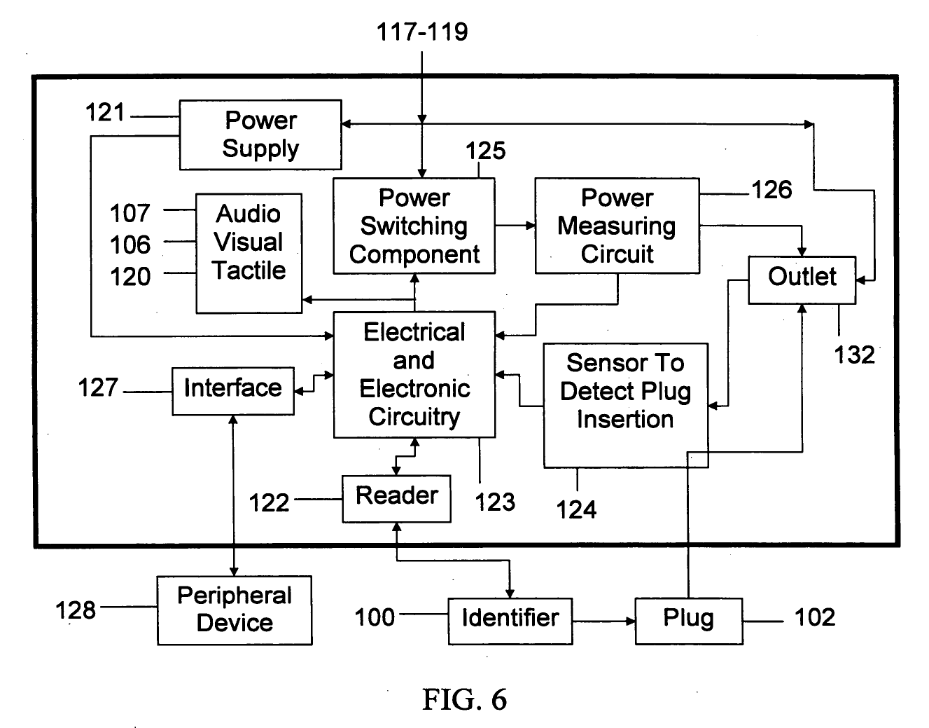

FIG. 6 illustrates a block diagram of the Enhanced Power Outlet System with Smart Receptacle. AC power is supplied to the receptacle from conductors 117-119. The power required to drive the electrical and electronic circuits and components in the Smart Receptacle is provided by a power supply 121 such as an AC/DC converter. One embodiment is for a user to make available the identifier 100 to the Smart Receptacle reader 122. The identifier code obtained by the reader 122 from the identifier 100 is checked against an authorization list which can be held in the reader 122 memory, in a microprocessor in the electrical and electronic circuitry 123, or in a peripheral device 128 accessed through the interface 127. The electrical and electronic circuitry 123 can send the identifier code through the interface 127 to a peripheral device 128 containing the authorization list and communicate the validation back to the electrical and electronic circuitry 123 through the interface 127. Once the identifier 100 has been validated, the audio 107, visual 106, or tactile 120 components can be used to notify the user of successful validation. A sensor to detect plug insertion 124 can be used by the electrical and electronic circuitry 123 for additional authorization. After complete authorization including identifier validation, and plug insertion, power is provided by power switching components 125 to at least one receptacle 132. Once the device plugged into the receptacle is in operation, a power measuring circuit 126 keeps track of power dissipated by said device, time the receptacle is in use, or that it is used by said user and relays this information to the electrical and electronic circuitry 123 which can, through interface 127, communicate this information to peripheral device 128. An operator can access and manage the information in peripheral device 128. Additionally, an operator can access and manage the information stored in the electronic and electrical circuitry 123 or reader 122 (an example of which is an RFID reader) using the interface 127 and peripheral device 128. When the plug insertion sensor 124 detects that the plug 102 is removed or after a preset time interval or another metric, the power is disabled by the electrical and electronic circuitry 123 in conjunction with the power switching components 125 and the receptacle is reset ready to restart the process.

### Operation—Preferred Embodiment

The preferred embodiment is an enhanced power outlet system with a smart receptacle where the user has an identifier which is used by the reader in the smart receptacle to identify the user. The identification is then employed to validate, and authorize the user. The user is then informed that power is enabled by an audio, visual, or tactile indicator followed by power supplied to the identified outlet after full insertion of the plug. The power usage is monitored and recorded until the plug is removed. The power usage data is then used to assess work efficiency or charge the user a fee for power usage. An operator can control the authorization list, access power usage data, and manage the account. In the preferred embodiment the facility has smart receptacles within external enclosures secured to all accessible existing outlets or smart receptacles hardwired to the building's power supply for all accessible built-in outlets.

In one embodiment the smart receptacle contains an RFID reader, and the user has a passive RFID tag with a unique identifier within a hand-held card. The smart receptacle communicates via X-10 technology, a wireless network, or a hard wired network to a central computer containing an authorized user list. Power is supplied to an indicated outlet after the user is authorized. Power usage is monitored in the receptacle and communicated to the central computer. Users are charged a fee based on instances of usage, time of usage, or power consumed during usage in accordance with a prearranged agreement. Alternatively, power usage is employed to assess work efficiency. Reports detailing usage data are made available to the operator or user as desired.

Applications of the enhanced power outlet system with smart receptacle include deployment in public facilities such as airports, trains, or other locations where people can user power outlets and be charged for their usage. Another application is to monitor work efficiency in a workplace where employees use power from different outlets. An example of this application is to monitor housekeepers in hotels where the use of a vacuum cleaner with an associated identifier tag plugged into the outlet in each room can be monitored to assess work efficiency. Other applications include in the household or other living facilities (e.g., nursing homes) where young children or people with dementia reside and are at risk of electrocution; in this setting, the receptacles can be programmed to only supply power to valid appliances to prevent injury. Another application is at business facilities where power is available to charge battery-powered electric motor vehicles or to heat the engine blocks of motorized vehicles in very cold weather. In the setting of an electric motor vehicle power station, analogous to a gas station, a credit card can be employed to identify the user and charge a fee. Such a system may also be instituted in public or business parking lots, for example, hotel parking lots where patrons can use their room key to activate the smart receptacle or at a workplace where patrons use an identification badge. Further applications include workplaces such as factories or hotels where workers take powered equipment from one location to another; in these settings usage data can be used to assess work efficiency.

### Conclusion, Ramifications, and Scope

Thus, the reader will see that, according to the invention, the system described can be implemented in an existing home or commercial location or installed to replace such systems. This system is easily understood and used.

While the above description contains many specificities, these should not be construed as limitations on the scope of the invention, but as exemplifications of the presently preferred embodiments thereof Many other ramifications and variations are possible within teachings of the invention. For example, this system could be implemented in public and commercial areas such as airports to charge subscribers a fee for using an electrical receptacle. Another example is to use this system at battery-powered motor vehicle power charging stations, analogous to gas stations Or, this system could be installed in child care facilities, schools, or senior citizen homes where the chances for electrical shock are higher or usage of power is restricted to authorized personnel. Another application is to incorporate this system into a facility where worker productivity can be correlated to power usage to track worker efficiency. An example of this is a hotel where the vacuum cleaner's plugs have embedded RFID tags enabling monitoring the amount of time each housekeeper uses the vacuum per room. In this latter example, involving portable electrically powered devices associated with a specific worker, the outlet may always be on but when a recognized RFID tag is brought into the vicinity of the receptacle, power usage is monitored and associated with the specific device and worker.

The receptacle described in this application can either be installed internally within a structure or can be produced as an adapter which can be plugged into and secured to an existing outlet. The entire system can be customized and produced in different shapes and colors. The smart receptacles can include single features of only identifying valid users, only controlling power delivery to validated users, only monitoring consumption of power for given users, or only allowing power to a device when a plug is fully inserted into the receptacle. The receptacle is able to be produced with one, all, or any combination of the above mentioned features.

While embodiments of this invention have been illustrated in the accompanying drawings and described above, it will be evident to those skilled in the art that changes and modifications may be made therein without departing from the essence of this invention. All such modifications or variations are believed to be within the scope of the invention as defined by the claims appended hereto.

Thus, the scope of the invention should be determined by the appended claims and their legal equivalents, and not by the examples given.

We claim:

1. A power outlet system comprising:
a power outlet receptacle;
a system to identify a user; and
circuitry to control power to the receptacle; whereby only an authorized user will be able to obtain power from the receptacle.

2. A power outlet system according to claim 1, wherein the receptacle includes internal circuitry to authorize the approved user.

3. A power outlet system according to claim 1, wherein the receptacle includes internal circuitry to communicate to a remote processor to obtain authorization information for the approved user.

4. A power outlet system according to claim 1, wherein the type of power provided by the receptacle is selected from the group consisting of alternating current electricity, direct current electricity, electromagnetic induction, light, laser, maser, optical means, electromagnetic means, audio means, chemical means, and mechanical means.

5. A power outlet system according to claim 1, wherein the receptacle includes a sensor to detect when an associated device plug is inserted.

6. A power outlet system according to claim 1, wherein the receptacle includes a system to communicate the user's power consumption data to a remote processor.

7. A power outlet system according to claim 1, wherein the means to communicate the authorized user's power consumption data is selected from the group consisting of telecommunication lines, power lines, wireless means, optical means, electromagnetic means, audio means, and human transfer of data.

8. A power outlet system according to claim 1, wherein the authorized user is charged a fee for use of power obtained from the receptacle.

9. A power outlet system according to claim 1, wherein the authorized user's power consumption data is used to track work productivity.

10. A power outlet system according to claim 1, wherein the receptacle includes a device to confirm to the authorized user that the power supply is enabled is selected from the group consisting of speakers, buzzers, vibrators, plungers, and lights.

11. A power outlet system according to claim 1, wherein the authorized user is an authorized person powering a device.

12. A power outlet system according to claim 1, wherein the receptacle is contained within an external enclosure which can be inserted into an existing power outlet.

13. A power outlet system according to claim 12, wherein the external enclosure containing the receptacle can be locked onto an existing power outlet.

14. A power outlet system according to claim 1, wherein the reader used to identify the authorized user, associated with the receptacle, is selected from the group consisting of magnetic card readers, optical readers, universal product code readers, biometric readers, radio frequency identification readers, mechanical lock and key systems, and electronic circuitry.

15. A power outlet system according to claim 1, wherein the identifier, associated with the authorized user, is selected from the group consisting of magnetic cards, optical data, universal product codes, biometrics, radio frequency identification tags, keys, and electronic circuitry.

16. A power outlet system according to claim 1, wherein electronic circuitry associated with the reader that is associated with the one receptacle is able to power the identifier, activating electronic circuitry within the identifier, enabling communication with the reader to allow authorization.

17. A power outlet system according to claim 1, wherein the system to identify the at authorized user includes an identifier contained within an adaptor that mates with a device plug on one end and the receptacle on the other end.

18. A power outlet system according to claim 17, wherein the adaptor can be locked onto a device plug.

19. A power outlet system according to claim 17, wherein the adaptor has a non-standard array of prongs that mate with the receptacle that has the reciprocal non-standard array of prong holes.

20. A power outlet system comprising:
a power outlet receptacle;
a system to identify a user; and
circuitry to monitor usage at the receptacle, wherein usage of power at the receptacle will be tracked for each user.

21. A power outlet system according to claim 20, which further includes a system to communicate the user's usage data to a remote processor.

22. A power outlet system according to claim 20, wherein the user's power consumption data is used to measure work productivity.

23. A system according to claim 20, wherein the receptacle contains circuitry to control power.

24. A system according to claim 20, wherein the receptacle contains circuitry to monitor power consumption.

25. A system according to claim 20, wherein the receptacle communicates to a remote processor.

26. A method consisting of charging the user a monetary fee based upon power usage at a power outlet, comprising:
a power outlet system that controls power to a receptacle;
a means of identifying a user;
a means of communicating the user's usage information to a remote processor;
an accounting system that collects the user's usage information; and
an accounting system that charges the user a monetary fee.

27. A method according to claim 26, wherein the accounting system charges the user a monetary fee based upon cumulative usage of power over a time interval at the receptacle.

28. A method according to claim 26, wherein the accounting system charges the user a monetary fee once a specified amount of usage is attained.

29. A method according to claim 26, wherein the accounting system charges the user a monetary fee based upon the number of discrete times power is used by the user.
